(19) United States
(12) Patent Application Publication
(10) Pub. No.: US 2026/0245619 A1
(43) Pub. Date: Aug. 20, 2026

(54) WRITE TIME REDUCTION CIRCUIT ARCHITECTURE FOR RRAM

(71) Applicant: GlobalFoundries U.S. Inc., Malta, NY (US)

(72) Inventors: Siva Kumar Chinthu, Bangalore (IN); Palle Sundar Veerendranath, Andhra Pradesh (IN); Vivek Sharma, Bangalore (IN); Nitish Kumar, Bangalore (IN)

(21) Appl. No.: 19/053,621

(22) Filed: Feb. 14, 2025

(51) Int. Cl. G11C 13/00; G11C 5/14

(52) U.S. Cl. CPC G11C 13/0038; G11C 5/145; G11C 13/0059

(57) ABSTRACT

A resistive random-access memory (RRAM) structure. The structure includes: a read/write switch including: a charge pump having an input node coupled to a low voltage and an output node that continuously generates a high voltage; a first transistor coupled in series between the output node of the charge pump and a switch output; a second transistor coupled between a source voltage and the switch output; and a level shifter (LS) having a first LS output coupled to a gate of the first transistor and a second LS output coupled to a gate of the second transistor.

### TECHNICAL FIELD

The present disclosure relates generally to circuits for performing read and write operations in resistive random-access memory (RRAM) structures, and more particularly to a write time reduction circuit architecture for RRAM devices.

### BACKGROUND

Resistive random-access memory (also referred to as ReRAM or RRAM) is a type of non-volatile random-access computer memory that works by changing the resistance across a dielectric solid-state material, often referred to as a memristor. RRAM operations are implemented, e.g., by (1) using a high voltage to create or break a conductive filament to perform a write operation and (2) using a small voltage to measure current flow to perform a read operation. In certain cases, write operations are performed with alternating “write” and “read verify” cycles in which data is written, then data is read for verification, then data is written, then data is read for verification, etc. Typically, the peripheral circuitry of an RRAM includes a charge pump, which is enabled during high voltage write operations and disabled during low voltage read operations. This requirement to continuously switch between high and low voltages on the read/write bus by enabling and disabling the charge pump presents various technical challenges (e.g., results in an undesirably long write time due to charge pump ramp up/down times).

### SUMMARY

All aspects, examples and features mentioned below can be combined in any technically possible way.

An aspect of the disclosure provides a resistive random-access memory (RRAM) structure. The structure includes: a read/write switch including: a charge pump having an input node coupled to a low voltage and an output node that continuously generates a high voltage; a first transistor coupled in series between the output node of the charge pump and a switch output; a second transistor coupled between a source voltage and the switch output; and a level shifter (LS) having a first LS output coupled to a gate of the first transistor and a second LS output coupled to a gate of the second transistor.

Another aspect of the disclosure provides a read/write switch for a resistive random-access memory (RRAM) structure, comprising: a charge pump having an input node coupled to a low voltage and an output node that continuously generates a high voltage; a first transistor coupled in series between the output node of the charge pump and a switch output; a second transistor coupled between a source voltage and the switch output; and a level shifter (LS) having a first LS output coupled to a gate of the first transistor and a second LS output coupled to a gate of the second transistor.

A further aspect of the disclosure provides a resistive random-access memory (RRAM) structure, comprising: a read/write switch including: a charge pump having an output node that generates a charge pump output voltage that is variable; a first transistor coupled in series between the output node of the charge pump and a switch output; a second transistor coupled between a source voltage and the switch output; a level shifter (LS) having an enable input that receives a source voltage during a write operation and 0 volts during a read operation, wherein the LS includes a first LS output coupled to a gate of the first transistor and a second LS output coupled to a gate of the second transistor; and a high voltage selection switch that provides a highest voltage to the LS selected between the source voltage and the charge pump output voltage.

Two or more aspects described in this disclosure, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a traditional read/write switch layout and timing diagram for an RRAM structure;

FIG. 2 shows a circuit for implementing the read/write switch layout of FIG. 1A;

FIG. 3 shows a read/write switch layout and timing diagram for an RRAM structure according to embodiments of the disclosure;

FIG. 4 shows a circuit diagram of the read/write switch of FIG. 2A, according to embodiments of the disclosure;

FIG. 5 shows a circuit diagram for a variable read/write switch with voltage values, according to embodiments of the disclosure; and

FIG. 6 shows a table of voltage values for the read/write switch of FIG. 3 according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which are shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

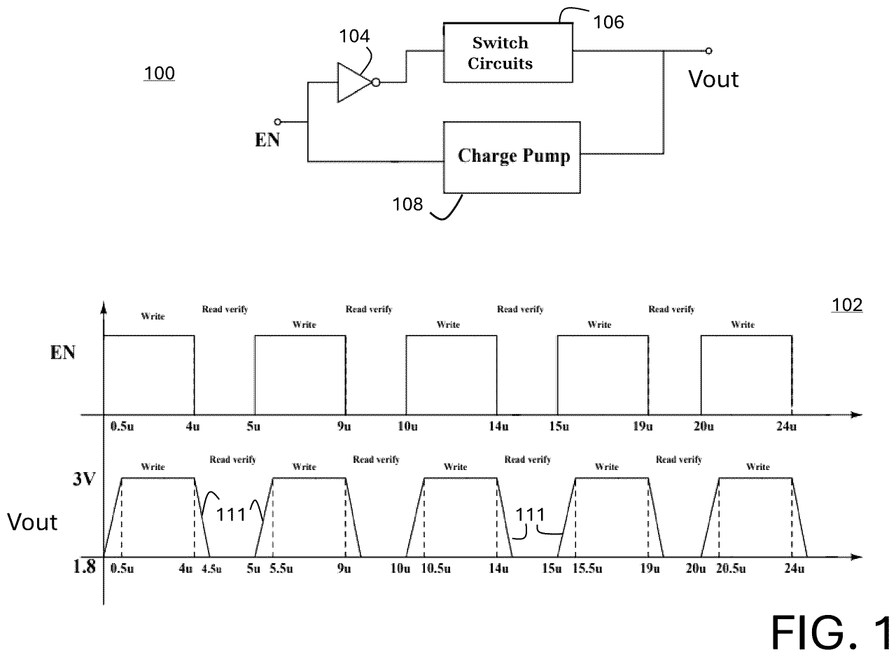

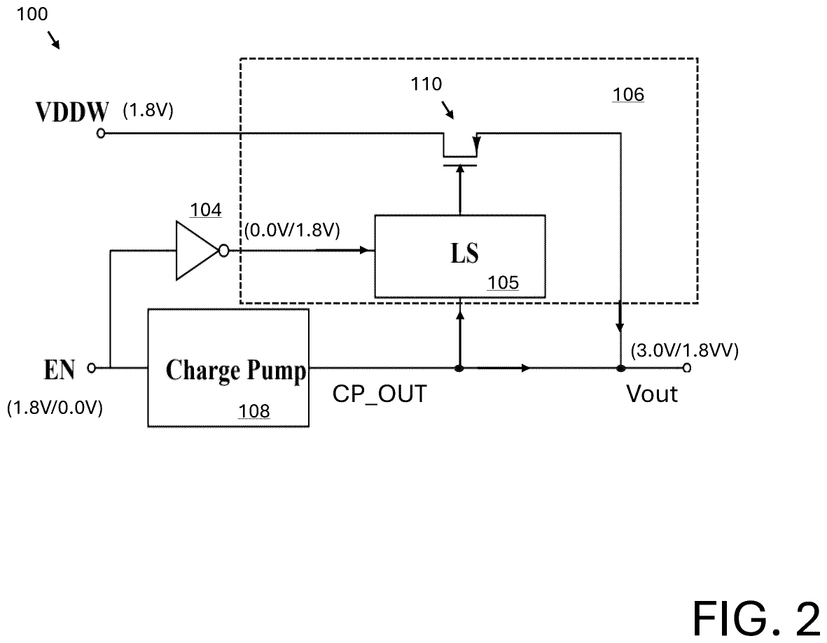

As mentioned above, in RRAM peripheral circuitry, the requirement to continuously switch between high and low voltages on the read/write bus by enabling and disabling the charge pump presents various technical challenges (e.g., results in an undesirably long write time due to charge pump ramp up/down times). For example, FIG. 1 depicts a traditional read/write switch architecture (i.e., scheme) 100 and associated timing diagram 102 for an RRAM structure. FIG. 2 depicts an illustrative circuit for implementing scheme 100, which includes an enable (EN) signal and an inverter 104 having an input coupled to the EN signal and an output coupled to an input of switch circuits 106. A charge pump 108 operates in parallel to the switch circuits 106, and has an input coupled to the EN signal and outputs a charge pump output signal (CP_out). Both the switch circuits 106 and charge pump 108 outputs are coupled together at the output Vout. Switch circuits 106 include: a P-type field effect transistor (PFET) 110 connected between a positive supply voltage (VDDW) node (e.g., at 1.8V) and output Vout.; a level shifter (LS) 105 having inputs connected to receive outputs of inverter 104 and charge pump 108 and an output connected to the gate terminal of PFET 110.

As can be seen in the associated timing diagram 102 (FIG. 1), the EN signal toggles on (e.g., 1.8V) and off (e.g., 0.0V) during alternating write and read verify cycles, which in this case results in output Vout toggling between 3.0V and 1.8V, respectively. More specifically, when EN is at 1.8V, charge pump 108 is enabled and CP_out is at 3.0V. Additionally, level-shifter 105 receives inputs of 0.0V from inverter 104 and 3.0V from charge pump 108 and outputs a gate control signal of 3.0V to PFET 110. As a result, PFET 110 remains in off and output Vout is at 3.0V. When EN is at 0.0V, charge pump 108 is disabled and CP_OUT is 0.0V. Additionally, level-shifter 105 receives inputs of 1.8V from inverter 104 and 0.0V from charge pump 108 so that the gate control signal for PFET 110 switches to 0.0V. As a result, PFET 110 turns on and output Vout drops to 1.8V. However, because charge pump 108 has an inherent delay when turned on and off by EN signal, the output Vout includes ramp up and ramp down transitions 111, which increases rise and fall time times and slows write operations. Namely, the additional rise and fall times require a greater number of clock cycles to complete a write operation. In the example shown, a 0.5 microsecond (μs) penalty is paid for each rise and fall transition.

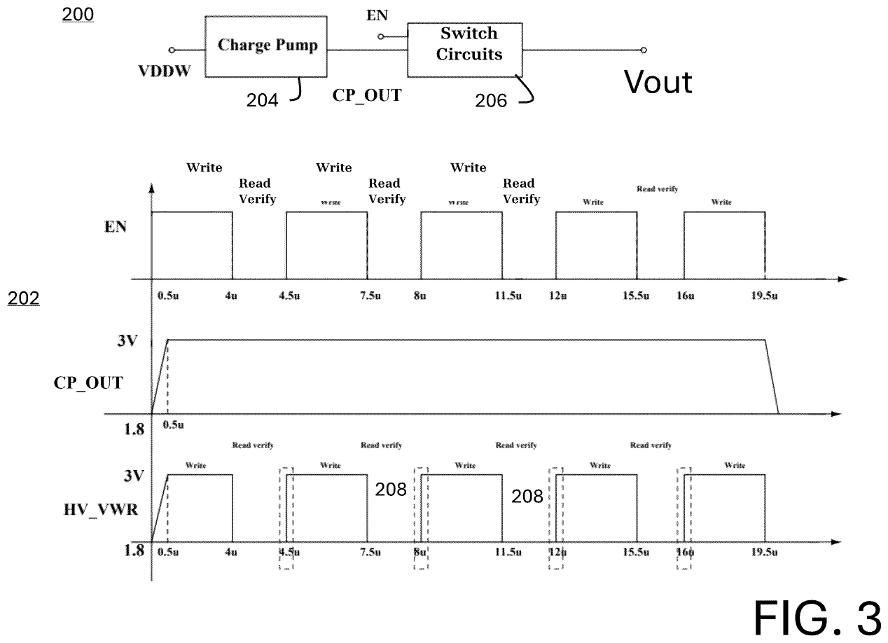

FIG. 3 depicts an alternative read/write switch scheme 200 in which the charge pump 204 is arranged in series with switch circuits 206. In this case, charge pump 204 is continuously ON, i.e., the enable signal EN is only input to switch circuits 206. As shown in the associated timing diagram 202, CP_OUT, which is the output of the charge pump 204, remains at the higher voltage level (3V in this case) during a write operation. As a result, the switch output Vout, which is not impacted by a toggling charge pump, has very minimal rise and fall delay 208, e.g., 50 nanoseconds (ns). Accordingly, using scheme 200, fewer clock cycles are required to complete a write operation as compared with scheme 100 (FIG. 1). In this example, the write save percentage is about 16.5%.

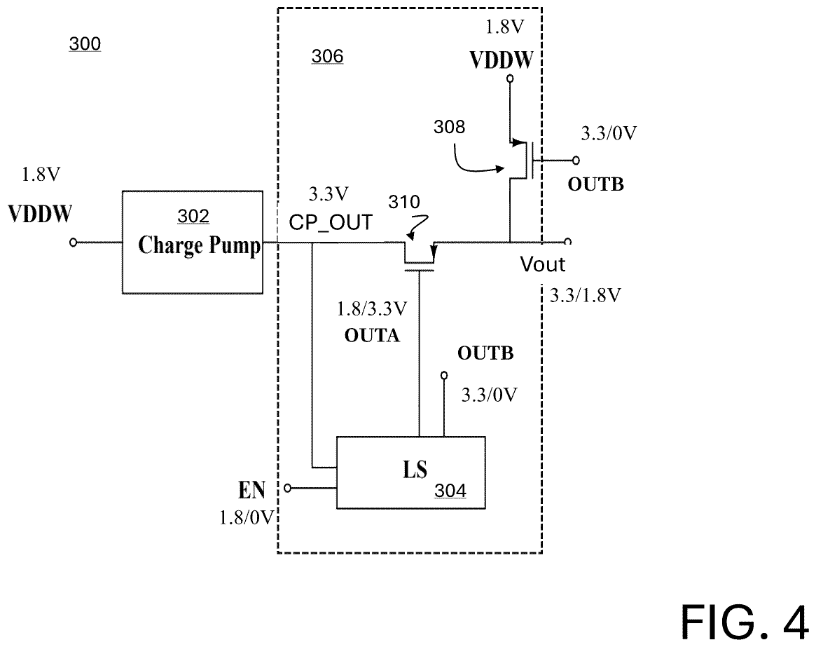

FIG. 4 depicts an illustrative circuit schematic of a read/write switching circuit 300 for implementing the switch scheme 200 of FIG. 3. As shown, charge pump 302 and switch circuits 306 are arranged in series. Charge pump 302 receives as input a low voltage (in this case source voltage VDDW of 1.8V) and outputs a charge pump output signal (CP_out) at 3.3V. Switch circuits 306 include a multi-output level shifter (LS) 304, first transistor 310, and a second transistor 308. In this example, first transistor 310 comprises a p-type metal oxide semiconductor (PMOS), having a drain coupled to the charge pump 302 and source coupled to the switch output Vout. Level shifter (LS) 304 receives as inputs the output of charge pump 302 (e.g. 3.3V) and enable signal (EN) which toggles between 1.8 and 0V, and outputs a first level shifted signal OUTA to the gate of first transistor 310 and further outputs a second level shifted signal OUTB. Namely, when the EN signal is 1.8V, LS 304 outputs 1.8V to the gate of first transistor 310, which activates first transistor 310 and passes 3.3V to the switch output Vout. When the EN signal is 0V, LS 304 outputs 3.3V to the gate which deactivates first transistor 310 blocking the charge pump 302 output from reaching switch output Vout.

A second transistor 308 is coupled between source voltage VDDW (1.8V) and switch output Vout and is gated by a second LS output, OUTB. OUTB activates/deactivates second transistor 308, allowing or blocking VDDW (1.8V) from reaching the switch output Vout. In this case, second transistor 308 comprises a PMOS having a source coupled to VDDW and drain coupled to output Vout. When the EN signal is 0V, LS 304 outputs 0V (OUTB) to the gate of the second transistor 308 which activates second transistor 308 and results in a switch output Vout of 1.8V. When the EN signal is 1.8V, LS 304 outputs 3.3V (OUTB) to the gate of the second transistor 308 which deactivates second transistor 310, blocking VDDW from reaching output Vout. Accordingly, using this circuit 300, output Vout toggles between 3.3V and 1.8V in response to the EN signal toggling between 1.8V and 0V with minimal transition delays.

Accordingly, by configuring the first transistor 310 in series between the charge pump 302 and output Vout, the write time of the switching circuit 300 is reduced. As a further advantage, switching circuit 300 allows for the use of low voltage devices 310, 308 (e.g., 1.8V), which are maintained within a safe operating area (SOA).

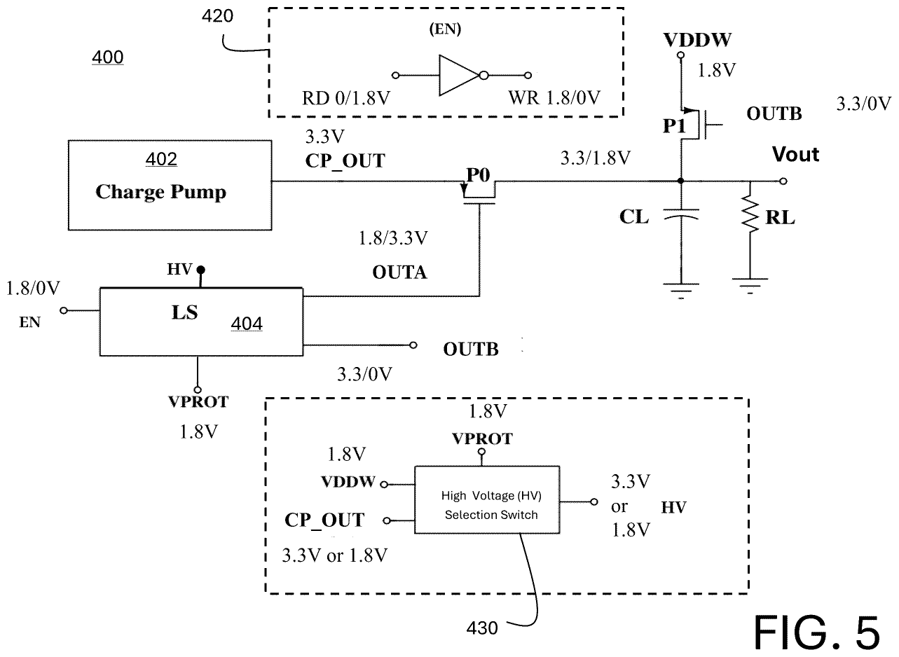

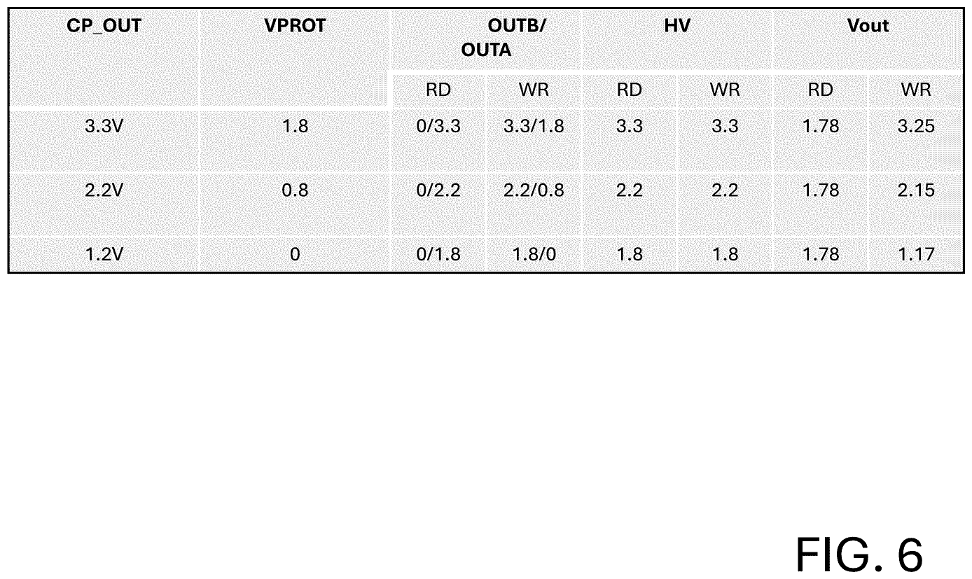

FIG. 5 depicts a more detailed illustrative circuit 400 for a more complex read/write switch wherein the charge pump output (CP_OUT) is variable (e.g., at 3.3V for a high voltage write mode, 2.2V for a mid-voltage write mode, and 1.2V for a low voltage write mode). In this example, the charge pump output (CP_OUT) is 3.3. Voltages for other CP_OUT values are provided in FIG. 6, ranging from 1.2V up to 3.3V.

Because CP_OUT is variable in the structure of FIG. 5, the switch circuits portion of the structure needs to be a bit more complicated and particularly needs to include a selection switch 430 to control the outputs of the level shifter 404 in order to ensure that the first transistor (P0) and second transistor (P0) turn on/off when they are supposed to. For example, if only the switch circuits 306 of FIG. 4 was implemented, when CP_OUT dropped to 1.2V during a low voltage write-mode, PFET 310 would not turn on even when EN was at 1.8V so that the output of level shifter 304 was at 1.8V.

In this case (CP_OUT =3.3V), the enable signal EN, which is coupled to level shifter (LS) 404, toggles between 1.8V and 0V using inverter 420, which cycles between a write signal WR and a read signal RD. Further, level shifter (LS) 404 also includes as input a protection voltage VPROT of 1.8V, and HV. HV is generated by high voltage selection switch 430, which outputs the higher of VDDW (1.8V) and CP_OUT. If CP_OUT is 3.3V, then switch 430 outputs 3.3V. If HV_VWR is 1.8V, then switch 430 outputs 1.8V. The purpose of high voltage selection switch 430 is to ensure proper functionality in the case that the output CP_OUT of charge pump 402 is less than 1.8V. For example, if the output CP_OUT of charge pump 402 is 1.2V during a read operation, then the gate voltage of the first transistor P0 of 1.8V will turn off P0, potentially resulting in leakage to the charge pump 402. Circuit 400 also includes a load capacitor CL of, e.g., 150 picofarads, and a load resistor RL of, e.g., 1.6 kiloohms, coupled to switch output Vout.

Generally, for write operations:
a. If CP_OUT is at 3.3V, HV will be at 3.3V and VPROT will be at 1.8V. If RD EN is low (i.e., during a write operation), then OUTA that controls P0 will be at 1.8V and OUTB that controls P1 will be at 3.3V. So P0 is on and P1 is off and Vout is at approximately 3.3V. The table of FIG. 6 says 3.25V as there will be some loss.
b. If CP_OUT is at 2.2V, HV will be at 2.2V and VPROT will be at 0.8V. If RD EN is low (i.e., during a write operation), then OUTA that controls P0 will be at 0.8V and OUTB that controls P1 will be at 2.2V. So P0 is on and P1 is off and Vout is at approximately 2.2V. The table says 2.15V as there will be some loss.
c. If CP_OUT is at 1.2V, HV will be at 1.8V and VPROT will be at 0.0V. If RD EN is low (i.e., during a write operation), then OUTA that controls P0 will be at 0.0V and OUTB that controls P1 will be at 1.8V. So P0 is on and P1 is off and Vout is at approximately 1.2V. The table says 1.17V as there will be some loss.

For Read operations:
a. If CP_OUT is at 3.3V, HV will be at 3.3V and VPROT will be at 1.8V. If RD EN is high (i.e., during a read operation), then OUTA that controls P0 will be at 3.3V and OUTB that controls P1 will be at 0.0V. So P0 is off and P1 is on and Vout is at approximately 1.8V. The table says 1.78V as there will be some loss.
b. If CP_OUT is at 2.2V, HV will be at 2.2V and VPROT will be at 0.8V. If RD EN is high (i.e., during a read operation), then OUTA that controls P0 will be at 2.2V and OUTB that controls P1 will be at 0.0V. So P0 is off and P1 is on and Vout is at approximately 1.8V. The table says 1.78V as there will be some loss.
c. If CP_OUT is at 1.2V, HV will be at 1.8V and VPROT will be at 0.0V. If RD EN is high (i.e., during a read operation), then OUTA that controls P0 will be at 1.8V and OUTB that controls P1 will be at 0.0V. So P0 is off and P1 is on and Vout is at approximately 1.8V. The table says 1.78V as there will be some loss.

While the circuit examples shown in FIGS. 4 and 5 utilize 1.8V for the source voltage VDDW, and 3.3V for the higher voltage output by the charge pump, it is understood that other voltage levels could likewise be utilized.

For the purposes of the present embodiments, a MOSFET refers to a transistor with a semiconductor channel region positioned laterally between a source region and a drain region and with a gate (e.g., including a gate dielectric-gate conductor stack) adjacent to the channel region. However, it should be understood that the figures and discussion thereof are not intended to be limiting. For example, alternatively, a similar circuit structure could be formed using bipolar junction transistors (BJTs) and, particularly, PNP BJTs and NPN BJTs.

The terminology used herein is for the purpose of describing particular embodiments only and is not intended to be limiting of the disclosure. As used herein, reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (A) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed. It will be further understood that the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not. It will be further understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A resistive random-access memory (RRAM) structure, comprising:
a read/write switch including:
a charge pump having an input node coupled to a low voltage and an output node that continuously generates a high voltage;
a first transistor coupled in series between the output node of the charge pump and a switch output;
a second transistor coupled between a source voltage and the switch output; and
a level shifter (LS) having a first LS output coupled to a gate of the first transistor and a second LS output coupled to a gate of the second transistor.

2. The RRAM structure of claim 1, wherein the LS includes an enable input that provides the low voltage during a write operation and 0 volts during a read operation.

3. The RRAM structure of claim 2, wherein the first LS output generates:
the low voltage during the write operation to activate the first transistor; and
the high voltage during the read operation to deactivate the first transistor.

4. The RRAM structure of claim 2, wherein the second LS output generates:
the high voltage during the write operation to deactivate the second transistor; and
0 volts during the read operation to activate the second transistor.

5. The RRAM structure of claim 1, wherein the low voltage comprises approximately 1.8 volts and the high voltage comprises approximately 3.3 volts.

6. The RRAM structure of claim 1, wherein the source voltage comprises 1.8V.

7. The RRAM structure of claim 1, wherein the first transistor and second transistor comprise p-type metal oxide semiconductors (PMOS).

8. A read/write switch for an resistive random-access memory (RRAM) structure, comprising:
a charge pump having an input node coupled to a low voltage and an output node that continuously generates a high voltage;
a first transistor coupled in series between the output node of the charge pump and a switch output;
a second transistor coupled between a source voltage and the switch output; and
a level shifter (LS) having a first LS output coupled to a gate of the first transistor and a second LS output coupled to a gate of the second transistor.

9. The read/write switch of claim 8, wherein the LS includes an enable input that provides the low voltage during a write operation and 0 volts during a read operation.

10. The read/write switch of claim 9, wherein the first LS output generates:
the low voltage during the write operation to activate the first transistor; and
the high voltage during the read operation to deactivate the first transistor.

11. The read/write switch of claim 9, wherein the second LS output generates:
the high voltage during the write operation to deactivate the second transistor; and
0 volts during the read operation to activate the second transistor.

12. The read/write switch of claim 8, wherein the low voltage comprises approximately 1.8 volts and the high voltage comprises approximately 3.3 volts.

13. The read/write switch of claim 8, wherein the source voltage comprises 1.8V.

14. The read/write switch of claim 8, wherein the first transistor and second transistor comprise p-type metal oxide semiconductors (PMOS).

15. A resistive random-access memory (RRAM) structure, comprising:
a read/write switch including:
a charge pump having an output node that generates a charge pump output voltage that is variable;
a first transistor coupled in series between the output node of the charge pump and a switch output;
a second transistor coupled between a source voltage and the switch output;
a level shifter (LS) having an enable input that receives a source voltage during a write operation and 0 volts during a read operation, wherein the LS includes a first LS output coupled to a gate of the first transistor and a second LS output coupled to a gate of the second transistor; and
a high voltage selection switch that provides a highest voltage to the LS selected between the source voltage and the charge pump output voltage.

16. The RRAM structure of claim 15, wherein the charge pump output voltage varies between 1.2 volts, 2.2 volts, and 3.3 volts.

17. The RRAM structure of claim 16, wherein the LS receives a protection voltage as a further input.

18. The RRAM structure of claim 17, wherein the protection voltage is:
0 volts when the charge pump output voltage is 1.2 volts;
0.8 volts when the charge pump output voltage is 1.2 volts; and
1.8 volts when the charge pump output voltage is 3.3 volts.

19. The RRAM structure of claim 15, wherein the source voltage comprises 1.8V.

20. The RRAM structure of claim 15, wherein the first transistor and second transistor comprise p-type metal oxide semiconductors (PMOS).
